(19) United States
(12) Patent Application Publication
(10) Pub. No.: US 2019/0259610 A1
(43) Pub. Date: Aug. 22, 2019

(54) FILM FORMING METHOD AND METHOD OF MANUFACTURING SEMICONDUCTOR DEVICE

(71) Applicants: TOYOTA JIDOSHA KABUSHIKI KAISHA, Toyota-shi (JP); NATIONAL UNIVERSITY CORPORATION KYOTO INSTITUTE OF TECHNOLOGY, Kyoto-shi (JP)

(72) Inventors: Tatsuji NAGAOKA, Nagakute-shi (JP); Hiroyuki NISHINAKA, Kyoto-shi (JP); Shota MORIMOTO, Kyoto-shi (JP); Masahiro YOSHIMOTO, Kyoto-shi (JP)

(73) Assignees: TOYOTA JIDOSHA KABUSHIKI KAISHA, Toyota-shi (JP); NATIONAL UNIVERSITY CORPORATION KYOTO INSTITUTE OF TECHNOLOGY, Kyoto-shi (JP)

(21) Appl. No.: 16/269,180

(22) Filed: Feb. 6, 2019

(30) Foreign Application Priority Data
Feb. 22, 2018 (JP) 2018-030105

(51) Int. Cl. H01L 21/02; H01L 21/027

(52) U.S. Cl. CPC H01L 21/02565; H01L 21/0262; H01L 21/0276; H01L 21/02598

(57) ABSTRACT

A film forming method of forming a gallium oxide film doped with fluorine on a base body includes supplying a mist of a solution in which a gallium compound and a fluorine compound are dissolved to a surface of the base body while heating the base body. In this film forming method, the gallium oxide film doped with fluorine is generated on the surface of the base body. In this film forming method, the gallium oxide film doped with fluorine can be suitably formed on the surface of the base body.

### INCORPORATION BY REFERENCE

The disclosure of Japanese Patent Application No. 2018-030105 filed on Feb. 22, 2018 including the specification, drawings and abstract is incorporated herein by reference in its entirety.

### BACKGROUND

### 1. Technical Field

The present disclosure relates to a film forming method of forming a film on a base body, and a method of manufacturing a semiconductor device.

### 2. Description of Related Art

Japanese Unexamined Patent Application Publication No. 2017-162816 (JP 2017-162816 A) discloses a technique in which a film, which is formed of a metal oxide of gallium and contains fluorine as a dopant, is used as a transparent conductive film.

### SUMMARY

In JP 2017-162816 A, a method of forming a gallium oxide film containing fluorine as a dopant is not disclosed. The disclosure provides a method of suitably forming a gallium oxide film containing fluorine as a dopant.

A first aspect of the disclosure relates to a film forming method. In the film forming method, a gallium oxide film doped with fluorine is formed on a base body. This film forming method includes supplying a mist of a solution in which a gallium compound and a fluorine compound are dissolved to a surface of the base body while heating the base body.

When the mist of the solution (that is, the solution in which the gallium compound and the fluorine compound are dissolved) is supplied to the surface of the base body, the mist adheres to the surface of the base body. The mist adhered to the surface of the heated base body causes a chemical reaction on the base body. As a result, the gallium oxide film doped with fluorine is formed on the surface of the base body. With the film forming method according to the first aspect of the disclosure, the gallium oxide film doped with fluorine can be suitably formed on the surface of the base body.

In the film forming method according to the first aspect, the supplying of the mist of the solution in which the gallium compound and the fluorine compound are dissolved to the surface of the base body may include generating the mist from the solution in which both the gallium compound and the fluorine compound are dissolved, and supplying the mist of the solution in which both the gallium compound and the fluorine compound are dissolved to the surface of the base body.

In the film forming method according to the first aspect, the supplying of the mist of the solution in which the gallium compound and the fluorine compound are dissolved to the surface of the base body may include generating a mist from a solution in which the gallium compound is dissolved, generating a mist from a solution in which the fluorine compound is dissolved, and supplying the mist of the solution in which the gallium compound is dissolved and the mist of the solution in which the fluorine compound is dissolved to the surface of the base body.

In the film forming method according to the first aspect, the gallium oxide film may be a single crystal film.

In the film forming method according to the first aspect, the fluorine compound may be a compound containing fluorine and hydrogen.

In the film forming method according to the aspect, the fluorine compound may be hydrofluoric acid.

In the film forming method according to the aspect, the fluorine compound may be an ammonium compound.

In the film forming method according to the aspect, the fluorine compound may be ammonium fluoride.

In the film forming method according to the aspect, the fluorine compound may be ammonium hydrogen fluoride.

In the film forming method according to the first aspect, the gallium compound may be an organic material.

In the film forming method according to the aspect, the gallium compound may be a metal complex.

In the film forming method according to the aspect, the gallium compound may be gallium acetylacetonate.

In the film forming method according to the first aspect, the gallium compound may be a halide.

In the film forming method according to the aspect, the gallium compound may be gallium chloride.

In the film forming method according to the first aspect, the number of fluorine atoms dissolved in the solution may be no more than 10 times the number of gallium atoms dissolved in the solution.

In the film forming method according to the first aspect, the base body may be formed of gallium oxide.

In the film forming method according to the aspect, the base body may be formed of β-Ga₂O₃.

In the film forming method according to the aspect, the base body may be formed of α-Ga₂O₃.

In the film forming method according to the first aspect, the base body may be formed of α-Al₂O₃.

In the film forming method according to the first aspect, the gallium oxide film may be formed of β-Ga₂O₃.

In the film forming method according to the first aspect, the base body may be heated to 400° C. to 1000° C. in a case of forming the gallium oxide film.

A second aspect of the disclosure relates to a method of manufacturing a semiconductor device. The method includes forming the gallium oxide film according to the film forming method.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a view of a configuration of a film forming apparatus.

### DETAILED DESCRIPTION OF EMBODIMENTS

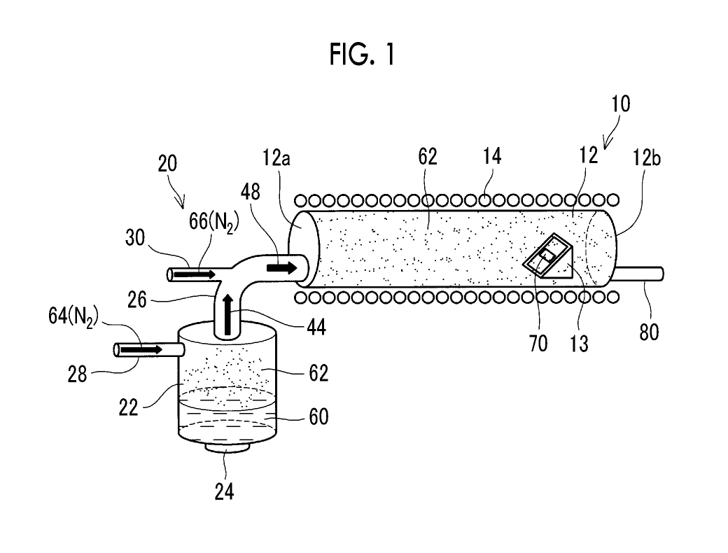

A film forming apparatus 10 illustrated in FIG. 1 is an apparatus that forms a gallium oxide film on a substrate 70. The film forming apparatus 10 includes a furnace 12 in which the substrate 70 is disposed, a heater 14 that heats the furnace 12, a mist supply device 20 connected to the furnace 12, and a discharge pipe 80 connected to the furnace 12.

The specific configuration of the furnace 12 is not particularly limited. As an example, the furnace 12 illustrated in FIG. 1 is a tubular furnace extending from an upstream end 12a to a downstream end 12b. A cross-section of the furnace 12 perpendicular to its longitudinal direction is circular. For example, the diameter of the furnace 12 may be 40 mm (in the specification, “40 mm” is a meaning including “about 40 mm”). However, the cross-section of the furnace 12 is not limited to the circular shape. The mist supply device 20 is connected to the upstream end 12a of the furnace 12. The discharge pipe 80 is connected to the downstream end 12b of the furnace 12.

In the furnace 12, a substrate stage 13 for supporting the substrate 70 is provided. The substrate stage 13 is configured to cause the substrate 70 to be inclined with respect to the longitudinal direction of the furnace 12. The substrate 70 supported by the substrate stage 13 is supported in such a direction that a mist flowing in the furnace 12 from the upstream end 12a to the downstream end 12b hits the surface of the substrate 70.

As described above, the heater 14 heats the furnace 12. The specific configuration of the heater 14 is not particularly limited. As an example, the heater 14 illustrated in FIG. 1 is an electric heater, and is disposed along the outer circumferential wall of the furnace 12. Accordingly, the heater 14 heats the outer circumferential wall of the furnace 12, whereby the substrate 70 in the furnace 12 is heated.

The mist supply device 20 supplies the mist of a solution containing the raw material of the gallium oxide film into the furnace 12. The specific configuration of the mist supply device 20 is not particularly limited. As an example, the mist supply device 20 illustrated in FIG. 1 includes a container 22 that stores a solution 60, an ultrasonic transducer 24 provided in the container 22, a mist supply passage 26 that connects the container 22 to the furnace 12, a carrier gas introduction passage 28 connected to the container 22, and a diluent gas introduction passage 30 connected to the mist supply passage 26. The carrier gas introduction passage 28 supplies a carrier gas 64 to the container 22. The diluent gas introduction passage 30 supplies a diluent gas 66 to the mist supply passage 26. The ultrasonic transducer 24 applies ultrasonic vibration to the solution 60 in the container 22 to generate a mist 62 of the solution 60.

The discharge pipe 80 is connected to the downstream end 12b of the furnace 12. The mist 62 supplied into the furnace 12 by the mist supply device 20 flows inside the furnace 12 to the downstream end 12b and is then discharged to the outside of the furnace 12 via the discharge pipe 80.

Next, a film forming method using the film forming apparatus 10 will be described. In Example 1, as the substrate 70, a substrate formed of a single crystal of β-gallium oxide (β-Ga₂O₃) having a (010) crystal plane exposed to the surface is used. In addition, in Example 1, as the solution 60, an aqueous solution in which gallium(III) chloride (GaCl₃ or Ga₂Cl₆) and ammonium fluoride (NH₄F) are dissolved is used. In the solution 60, the gallium chloride is dissolved at a concentration of 0.5 mol/L, and the ammonium fluoride is dissolved at a concentration of 0.05 mol/L. Furthermore, in Example 1, nitrogen gas is used as the carrier gas 64, and nitrogen gas is used as the diluent gas 66.

As illustrated in FIG. 1, first, the substrate 70 is placed on the substrate stage 13 in the furnace 12. Here, the substrate 70 is placed on the substrate stage 13 in such a direction that the (010) crystal plane of the substrate 70 becomes the upper surface (the surface exposed to the mist 62). Next, the substrate 70 is heated by the heater 14. Here, the temperature of the substrate 70 is controlled to 750° C. (in the specification, “750° C.” is a meaning including “about 750° C.”). When the temperature of the substrate 70 is stabilized, the mist supply device 20 is operated. That is, by operating the ultrasonic transducer 24, the mist 62 of the solution 60 in the container 22 is generated. At the same time, the carrier gas 64 is introduced into the container 22 from the carrier gas introduction passage 28, and the diluent gas 66 is introduced into the mist supply passage 26 from the diluent gas introduction passage 30. Here, the total flow rate of the carrier gas 64 and the diluent gas 66 is 5 L/min (in the specification, “5 L/min” is a meaning including “about 5 L/min”). The carrier gas 64 flows into the mist supply passage 26 through the container 22 as indicated by arrow 44. At this time, the mist 62 in the container 22 flows into the mist supply passage 26 together with the carrier gas 64. In addition, the diluent gas 66 is mixed with the mist 62 in the mist supply passage 26. Accordingly, the mist 62 is diluted. The mist 62 flows toward the downstream side in the mist supply passage 26 together with the nitrogen gas (that is, the carrier gas 64 and the diluent gas 66) and flows into the furnace 12 from the mist supply passage 26 as indicated by arrow 48. In the furnace 12, the mist 62 flows toward the downstream end 12b side together with the nitrogen gas and is discharged to the discharge pipe 80.

A portion of the mist 62 flowing in the furnace 12 adheres to the surface of the heated substrate 70. Then, the mist 62 (that is, the solution 60) causes a chemical reaction on the substrate 70. As a result, β-gallium oxide (β-Ga₂O₃) is formed on the substrate 70. Since the mist 62 is continuously supplied to the surface of the substrate 70, a β-gallium oxide film grows on the surface of the substrate 70. According to this film forming method, the β-gallium oxide film of a high-quality single crystal grows. In the β-gallium oxide film, fluorine atoms in the ammonium fluoride are incorporated as donors. Therefore, the β-gallium oxide film doped with fluorine is formed. The characteristics of the β-gallium oxide film formed by this film forming method were measured by Hall effect measurement, and a carrier density of 2.4×10¹⁹ cm⁻³ and a mobility of 40 cm²/Vsec were observed. As described above, according to the film forming method of Example 1, a high-quality β-gallium oxide film can be formed. In particular, in Example 1, since the β-gallium oxide film grows homoepitaxially on the substrate 70 formed of β-gallium oxide, a β-gallium oxide film with higher quality can be formed. In addition, since homoepitaxial growth is employed, conductivity control is facilitated.

Next, a film forming method of Example 2 will be described. In Example 2, a substrate formed of sapphire (Al₂O₃) is used as the substrate 70. In addition, in Example 2, as the solution 60, an aqueous solution in which gallium bromide (GaBr₃ or Ga₂Br₆) and ammonium hydrogen fluoride ((NH₄)HF₂) are dissolved is used. In the solution 60, the gallium bromide is dissolved at a concentration of 0.1 mol/L, and the ammonium hydrogen fluoride is dissolved at a concentration of 0.01 mol/L. In Example 2, nitrogen gas is used as the carrier gas 64, and nitrogen gas is used as the diluent gas 66.

In the film forming method of Example 2, as in Example 1, the substrate 70 is placed on the substrate stage 13, and the substrate 70 is heated by the heater 14. Here, the temperature of the substrate 70 is controlled to 500° C. (in the specification, “500° C.” is a meaning including “about 500° C.”). When the temperature of the substrate 70 is stabilized, the mist supply device 20 is operated. That is, the operation of the ultrasonic transducer 24, the introduction of the carrier gas 64, and the introduction of the diluent gas 66 are performed in the same manner as in Example 1. As a result, the mist 62 flows into the furnace 12, and a portion of the mist 62 flowing in the furnace 12 adheres to the surface of the heated substrate 70. Then, the mist 62 (that is, the solution 60) causes a chemical reaction on the substrate 70. As a result, α-gallium oxide (α-Ga₂O₃) is formed on the substrate 70. Since the mist 62 is continuously supplied to the surface of the substrate 70, an α-gallium oxide film grows on the surface of the substrate 70. According to this film forming method, the α-gallium oxide film of a high-quality single crystal grows. In the α-gallium oxide film, fluorine atoms in the ammonium hydrogen fluoride are incorporated as donors. Therefore, the α-gallium oxide film doped with fluorine is formed.

Next, a film forming method of Example 3 will be described. In Example 3, as the substrate 70, a substrate formed of a single crystal of β-gallium oxide having a (−201) crystal plane exposed to the surface is used. In addition, in Example 3, as the solution 60, an aqueous solution in which gallium(III) chloride (GaCl₃ or Ga₂Cl₆) and ammonium fluoride (NH₄F) are dissolved is used. In the solution 60, the gallium chloride is dissolved at a concentration of 0.5 mol/L, and the ammonium fluoride is dissolved at a concentration of 0.05 mol/L. Furthermore, in Example 3, nitrogen gas is used as the carrier gas 64, and nitrogen gas is used as the diluent gas 66.

In the film forming method of Example 3, as in Example 1, the substrate 70 is placed on the substrate stage 13. Here, the substrate 70 is placed on the substrate stage 13 in such a direction that the (−201) crystal plane of the substrate 70 becomes the upper surface (the surface exposed to the mist 62). Next, the substrate 70 is heated by the heater 14. Here, the temperature of the substrate 70 is controlled to 600° C. (in the specification, “600° C.” is a meaning including “about 600° C.”). When the temperature of the substrate 70 is stabilized, the mist supply device 20 is operated. That is, the operation of the ultrasonic transducer 24, the introduction of the carrier gas 64, and the introduction of the diluent gas 66 are performed in the same manner as in Example 1. As a result, the mist 62 flows into the furnace 12, and a portion of the mist 62 flowing in the furnace 12 adheres to the surface of the heated substrate 70. Then, the mist 62 (that is, the solution 60) causes a chemical reaction on the substrate 70. As a result, ε-gallium oxide (ε-Ga₂O₃) is formed on the substrate 70. Since the mist 62 is continuously supplied to the surface of the substrate 70, an ε-gallium oxide film grows on the surface of the substrate 70. According to this film forming method, the ε-gallium oxide film of a high-quality single crystal grows. In the ε-gallium oxide film, fluorine atoms in the ammonium fluoride are incorporated as donors. Therefore, the ε-gallium oxide film doped with fluorine is formed.

The film forming methods of Examples 1 to 3 have been described above. In all of the Examples 1 to 3 described above, the number (concentration) of fluorine atoms dissolved in the solution 60 is no more than 10 times the number (concentration) of gallium atoms dissolved in the solution 60. Since the solution 60 is used, in Examples 1 to 3, the gallium oxide film can be more suitably formed. In addition, in Examples 1 to 3, the substrate 70 is heated to 400° C. to 1000° C. By controlling the substrate 70 to a temperature within this range in a film forming process, the gallium oxide film can be more suitably formed.

In addition, in Examples 1 to 3, the substrate 70 is formed of β-gallium oxide or sapphire. However, the substrate 70 may be formed of another material. By using the substrate 70 formed of another material, a gallium oxide film having different characteristics from those of Examples 1 to 3 can be formed. For example, the substrate 70 may be formed of α-gallium oxide, γ-gallium oxide, δ-gallium oxide, ε-gallium oxide, or gallium nitride.

In addition, in Examples 1 to 3 described above, the gallium oxide film is formed on the surface of the substrate 70 (that is, a plate-shaped member). However, a member having another shape may be used as a base material, and a gallium oxide film may be formed on the surface of the base material.

In addition, in Examples 1 to 3, a fluorine compound dissolved in the solution 60 is ammonium fluoride or ammonium hydrogen fluoride. However, as the fluorine compound dissolved in the solution 60, another material may also be used. In addition, in order to form a high-quality gallium oxide film, for example, the fluorine compound is preferably a compound containing fluorine atoms and hydrogen atoms, and is more preferably ammonium compound. For example, as the fluorine compound, hydrofluoric acid (HF) or ammonium fluoroborate (NH₄BF₄) can be used. However, since the ammonium fluoride has relatively low toxicity and is easily dissolved in water, the ammonium fluoride is more suitable as the fluorine compound used for forming a gallium oxide film.

In addition, in Examples 1 to 3, a gallium compound dissolved in the solution 60 is gallium(III) chloride or gallium bromide. However, another material may be used as the gallium compound to be dissolved in the solution 60. In order to form a high-quality gallium oxide film, for example, the gallium compound is preferably an organic material. In particular, for example, the gallium compound is preferably a metal complex. Alternatively, the gallium compound may be a halide. For example, as the gallium compound, gallium acetylacetonate (for example, gallium(III) acetylacetonate (C₁₅H₂₁GaO₆)), gallium triacetate (C₆H₉GaO₆), or gallium iodide (GaI₃ or Ga₂I₆) can be used. However, since gallium chloride (particularly gallium(III) chloride) is inexpensive and can form a film with little residual impurities, the gallium chloride is more suitable as the gallium compound used for forming a gallium oxide film.

In addition, in Examples 1 to 3, the container 22 stores the solution 60 in which both the gallium compound and the fluorine compound are dissolved, a mist is generated from the solution 60, and the generated mist is supplied to the furnace 12. However, a first container storing a solution in which the gallium compound is dissolved and a second container storing a solution in which the fluorine compound is dissolved may be separately provided. Then, a first mist of the solution in which the gallium compound is dissolved may be generated in the first container, a second mist of the solution in which the fluorine compound is dissolved may be generated in the second container, and the first mist and the second mist may be supplied to the furnace 12.

In addition, in Examples 1 to 3, the substrate 70 is formed of β-Ga₂O₃ or Al₂O₃, the substrate 70 may also be formed of α-Al₂O₃.

In addition, in Examples 1 to 3, nitrogen is used as the carrier gas 64 and the diluent gas 66, but another gas such as an inert gas can be used as the carrier gas 64 and the diluent gas 66.

In addition, in Examples 1 to 3, the gallium oxide film of the single crystal is formed, but a polycrystalline or amorphous gallium oxide film may be formed.

Technical elements of the disclosure are listed below. Each of the following technical elements is independently useful.

In a film forming method of an example of the disclosure, the gallium oxide film may be a single crystal film.

By forming the gallium oxide film as a single crystal, the gallium oxide film can be used for a suitable semiconductor element.

In the film forming method of the example of the disclosure, the fluorine compound may be a compound containing fluorine and hydrogen. In addition, the fluorine compound may be an ammonium compound. In addition, the fluorine compound may be ammonium fluoride.

Since ammonium fluoride has low toxicity and is easily dissolved in water, the ammonium fluoride can be easily used in the film forming method of the disclosure.

In the film forming method of the example of the disclosure, the gallium compound may be a halide. In addition, the gallium compound may be gallium(III) chloride.

When the gallium(III) chloride is used, a high-quality gallium oxide film with little residual impurities can be formed.

In the film forming method of the example of the disclosure, the number of fluorine atoms dissolved in the solution may be no more than 10 times the number of gallium atoms dissolved in the solution.

With such a configuration, it is possible to more suitably form a gallium oxide film doped with fluorine.

In the film forming method of the example of the disclosure, a base body may be formed of gallium oxide. In addition, the base body may be formed of β-Ga₂O₃.

In the film forming method of the example of the disclosure, the gallium oxide film may be formed of β-Ga₂O₃.

With this configuration, the conductivity of the gallium oxide film can be more accurately controlled.

In the film forming method of the example of the disclosure, in a case where the gallium oxide film is formed, the base body may be heated to 400° C. to 1000° C.

While the embodiments have been described above in detail, these are merely examples and do not limit the scope of the claims. The technology described in the scope of the claims includes various modifications and changes of the specific examples exemplified above. The technical elements described in the disclosure or the drawings exhibit technical utility either singly or in various combinations, and are not limited to combinations described in the claims at the time of filing. The technology exemplified in the disclosure or the drawings accomplishes a plurality of objects at the same time, and has technical utility by itself achieving one of the objects.

What is claimed is:

1. A film forming method of forming a gallium oxide film doped with fluorine on a base body, the film forming method comprising supplying a mist of a solution in which a gallium compound and a fluorine compound are dissolved to a surface of the base body while heating the base body.

2. The film forming method according to claim 1, wherein the supplying of the mist of the solution in which the gallium compound and the fluorine compound are dissolved to the surface of the base body includes
generating the mist from the solution in which both the gallium compound and the fluorine compound are dissolved, and
supplying the mist of the solution in which both the gallium compound and the fluorine compound are dissolved to the surface of the base body.

3. The film forming method according to claim 1, wherein the supplying of the mist of the solution in which the gallium compound and the fluorine compound are dissolved to the surface of the base body includes
generating a mist from a solution in which the gallium compound is dissolved,
generating a mist from a solution in which the fluorine compound is dissolved, and
supplying the mist of the solution in which the gallium compound is dissolved and the mist of the solution in which the fluorine compound is dissolved to the surface of the base body.

4. The film forming method according to claim 1, wherein the gallium oxide film is a single crystal film.

5. The film forming method according to claim 1, wherein the fluorine compound is a compound containing fluorine and hydrogen.

6. The film forming method according to claim 5, wherein the fluorine compound is hydrofluoric acid.

7. The film forming method according to claim 5, wherein the fluorine compound is an ammonium compound.

8. The film forming method according to claim 7, wherein the fluorine compound is ammonium fluoride.

9. The film forming method according to claim 7, wherein the fluorine compound is ammonium hydrogen fluoride.

10. The film forming method according to claim 1, wherein the gallium compound is an organic material.

11. The film forming method according to claim 10, wherein the gallium compound is a metal complex.

12. The film forming method according to claim 11, wherein the gallium compound is gallium acetylacetonate.

13. The film forming method according to claim 1, wherein the gallium compound is a halide.

14. The film forming method according to claim 13, wherein the gallium compound is gallium chloride.

15. The film forming method according to claim 1, wherein the number of fluorine atoms dissolved in the solution is no more than 10 times the number of gallium atoms dissolved in the solution.

16. The film forming method according to claim 1, wherein the base body is formed of gallium oxide.

17. The film forming method according to claim 16, wherein the base body is formed of β-Ga₂O₃.

18. The film forming method according to claim 16, wherein the base body is formed of α-Ga₂O₃.

19. The film forming method according to claim 1, wherein the base body is formed of α-Al₂O₃.

20. The film forming method according to claim 1, wherein the gallium oxide film is formed of β-Ga₂O₃.

21. The film forming method according to claim 1, wherein the base body is heated to 400° C. to 1000° C. in a case of forming the gallium oxide film.

22. A method of manufacturing a semiconductor device, the method comprising forming the gallium oxide film according to the film forming method according to claim 1.
